(19) United States
(12) Patent Application Publication
(10) Pub. No.: US 2010/0134174 A1
(43) Pub. Date: Jun. 3, 2010

(54) Circuit Arrangement Comprising Feedback Protection For Switching In Power Applications

(75) Inventors: René Trapp, Fockelberg (DE); Mario Engelmann, Steinbach (DE)

Correspondence Address: RATNERPRESTIA, P.O. BOX 980, VALLEY FORGE, PA, 19482, US

(73) Assignee: CONTINENTAL TEVES AG & CO. OHG, Frankfurt (DE)

(21) Appl. No.: 12/161,224

(22) PCT Filed: Jan. 18, 2007
(86) PCT No.: PCT/EP2007/050495

§ 371 Date: Oct. 13, 2009

(30) Foreign Application Priority Data
Jan. 20, 2006 (DE) 102006003060.5
Feb. 15, 2006 (DE) 102006006878.5

(51) Int. Cl. H03K 17/687

(52) U.S. Cl. 327/436

(57) ABSTRACT

Disclosed is a circuit arrangement comprising feedback protection for switching the current flow in power applications. Said circuit arrangement comprises two serially connected MOSFETs (1, 2) on the conductor branch that is to be switched. Said MOSFETs are connected such that the inverse diodes thereof are arranged opposite each other regarding the PN junction.

### CROSS-REFERENCE TO RELATED APPLICATIONS

This application is the U.S. national phase application of PCT International Application No. PCT/EP2007/050495, filed Jan. 18, 2007, which claims priority to German Patent Application No. DE102006003060.5, filed Jan. 20, 2006 and German Patent Application No. DE102006006878.5, filed Feb. 15, 2006, the contents of such applications being incorporated by reference herein in their entirety.

### BACKGROUND OF THE INVENTION

1. Field of the Invention

The present invention relates to a circuit arrangement for regulating or controlling electric signals and quantities on the channels of sensors and/or sensor systems in motor vehicles, and a use thereof.

2. Description of the Related Art

It is known to use semiconductor elements as switches for power applications. In this context, the current flow in the corresponding feed line or the branch is interrupted by a semiconductor element by way of inducing the semiconductor element by external wiring to adopt a blocking condition or a high-ohmic condition.

Metal oxide semiconductor field effect transistors (mosfets) are frequently employed in the field of power applications. The mosfets generally include an inverse diode in parallel to the drain-source path. This inverse diode is achieved from the conventional internal wiring of the bulk with regard to the source connection, with the inverse diode representing the PN junction between bulk and drain. Furthermore, especially DMOS-fets (doubly diffused mosfets) include inverse diodes. This is due to their special design, and an inverse diode is characterized as a parasitic element in parallel to the drain-source path.

It is customary in particular in circuitries for power applications to implement a certain protection against fault currents which can cause failures in operation and destruction of delicate hardware. A special case of such fault currents can be seen in reverse current flow where current flow that is reverse to the normal working current occurs. This current flow is frequently induced by unwanted coupling of the energy supply, for example, due to insulation defects or wiring faults.

One single mosfet is not sufficient as a switch in a case of reverse current flow. Reverse current flow cannot be prevented by blocking of the mosfet because the inverse diode allows current flow in the opposite direction. To provide a remedy in this case, it is conventional practice to arrange a diode in series to the mosfet, and the diode is required to be reverse in its polarity with regard to the inverse diode of the mosfet. Any possible reverse current flow is prevented by this additional diode. However, a voltage of roughly 0.7 volt will drop at this diode when the mosfet is in its conductive state, with the result that the available voltage drops by this value.

It is technically rather inappropriate to use depletion layer fets (Jfets) although they are able to block in both directions because they are not suitable for power applications in particular. Likewise the use of bipolar transistors and insulated-gate transistors (IGBTs) is rather unsuitable since they can at most take up a blocking voltage of 7 to 8 volt due to the avalanche effect in the inverse direction. Thyristors are frequently used for switching purposes in power applications with currents starting with a magnitude of 100 ampere. However, thyristors are generally disadvantageous because they exhibit considerably longer switching times than mosfets and, therefore, are not suited for many applications. In addition, thyristors generally exhibit a problematic disconnecting behavior.

In view of the above, an object of the invention is to disclose a circuit arrangement for power applications which allows switching the current flow in a branch irrespective of the polarity of the voltage applied and which manages in the conductive state without noticeable voltage drop within the circuit arrangement itself.

### SUMMARY OF THE INVENTION

The object is achieved, according to aspects of the invention, by a circuit arrangement.

The invention relates to the idea of switching the current flow in a branch by means of a circuit arrangement which, in case that both mosfets are conductive, does not show any appreciable internal voltage drop owing to two mosfets being connected serially and oppositely with regard to the PN junctions of their inverse diodes, and which prevents current flow in both directions in the event that both mosfets block.

The term ‘branch’ implies the current path which is to be switched and, as the case may be, realizes the linking to a load to be switched. This may also concern a general electric supply channel.

A circuit arrangement of the invention is favorable because it can be realized with little effort and, furthermore, is easy to integrate into existing systems. A circuit arrangement according to aspects of the invention can be designed so as to be discrete, integrated on a separate chip or integrated into a more comprehensive system on a chip.

It is expedient that the branch includes a device for current measurement, in particular a resistor across which the voltage drop is measured. Reverse current flow and other fault currents can be detected thereby.

It may be preferred to apply the voltage that drops across the branch to a comparator, in which an offset voltage is predetermined in particular. An imminent potential reverse current flow can be detected by the comparison with a defined offset voltage.

Preferably, at least one mosfet gate drive is driven by electronic control logic, and the electronic control logic is linked to the measuring elements. The electronic control logic renders a variable actuation of the mosfets possible.

It may be preferred to supply the current measured in the branch to the electronic control logic. The logic will then evaluate the current with respect to defined threshold values or by means of an algorithm, and at least one mosfet gate drive is driven corresponding to the evaluation. The use of the control logic also allows putting special and complex evaluation or control methods into practice.

It is expedient that the measured current passes through an electronic filter prior to the evaluation by the electronic control logic. The electronic filter is used to filter harmless current fluctuations and current impulses so that reactions to these will not disturb the regular switching operation.

Embodiments of the circuit arrangement according to aspects of the invention principally can be achieved with n-channel mosfets and p-channel mosfets as well as with self-locking and self-conducting mosfets.

A circuit arrangement according to aspects of the invention as described hereinabove can be used in different ranges of power applications. Use in the sensor channel of a motor vehicle control system is especially suitable in this context. However, any other sensor channels can also be protected against reverse current flow. The circuit arrangement is also especially well suited for integration into integrated circuits which realize an energy-supplying actuation of loads. Furthermore, the invention relates to the use of the circuit arrangement for the regulation or control of the electric signals and quantities on the channels of the sensors and/or the sensor systems in motor vehicles.

These and other aspects of the invention are illustrated in detail by way of the embodiments and are described with respect to the embodiments in the following, making reference to the Figures.

### BRIEF DESCRIPTION OF THE DRAWINGS

The invention is best understood from the following detailed description when read in connection with the accompanying drawing. Included in the drawing are the following figures:

FIG. 1 is a circuit arrangement of the invention for switching the current flow in a branch with a device for current measurement and a device for voltage measurement, which send their data to an electronic control logic that drives two inventively connected mosfets by way of a gate drive in each case;

FIG. 2 is another circuit arrangement of the invention which switches a wheel rotational speed sensor channel, including a device for current measurement and evaluation; and

FIG. 3 shows the time variation of the current of a wheel rotational speed signal in a case of fault.

### DETAILED DESCRIPTION OF THE PREFERRED EMBODIMENTS

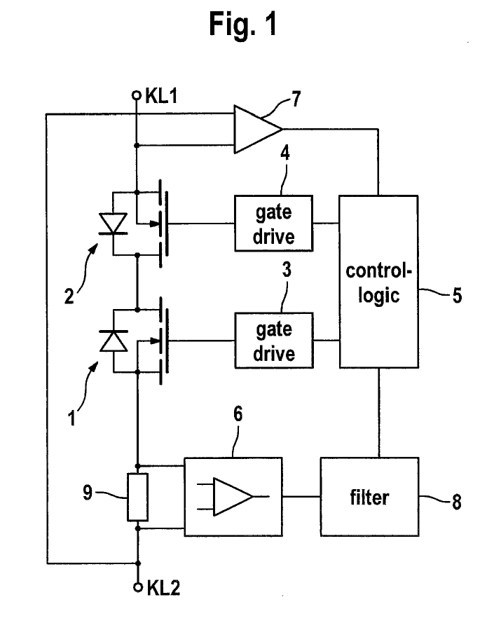

The circuit arrangement illustrated in FIG. 1 comprises two approaches being realized by circuit structure for detecting a reverse current flow or the possible beginning of reverse current flow. Both approaches are illustrated and explained by way of this circuit arrangement, while mostly one approach is sufficient for the technical realization. In the first place, the voltage drop across the branch is tapped and supplied to a comparator 7. As this occurs, both the polarity of the voltage and its value are detected. In consequence of a case of fault which can cause a change of polarity and, thus, a reverse current flow, this can be recognized already before by a considerable rapid drop of the voltage value. Since it is necessary to take a certain speed of reaction into consideration until the reverse current flow is blocked, it is advisable not to wait until a certain magnitude of a voltage of changed polarity is detected, but rather detect already the drop of the original voltage below a defined value. For this purpose, an offset voltage can be predetermined already for the comparator 7. In the example illustrated in FIG. 1, the output of the comparator is sent to the electronic control logic 5 which performs a more detailed evaluation, in particular an evaluation of the temporal voltage variation. Special algorithms can be used to this end. The electronic control logic 5 drives the two gate drives 3, 4 of the respective mosfets 1, 2, with the result that in the event of a reverse current flow or a fault of any other type, the branch is blocked in both directions or in one direction. This is possible because the two self-blocking n-channel mosfets 1, 2 are serially arranged opposite each other with respect to the PN junctions of their diodes. Secondly, the current through the branch is measured or monitored. This is done by means of the voltage drop across the resistor 9 and the evaluation unit 6 connected thereto. The voltage value is sent to the electronic control logic 5 by way of a filter 8. The purpose of filter 8 is to filter current fluctuations within defined limits from the following evaluation, since certain fluctuations of the signal are normal and shall not be included in the judgment of a possible deactivation or blocking. The electronic control logic 5 offers more extensive algorithms for evaluation, e.g. of the time variation of the current, or has defined current thresholds.

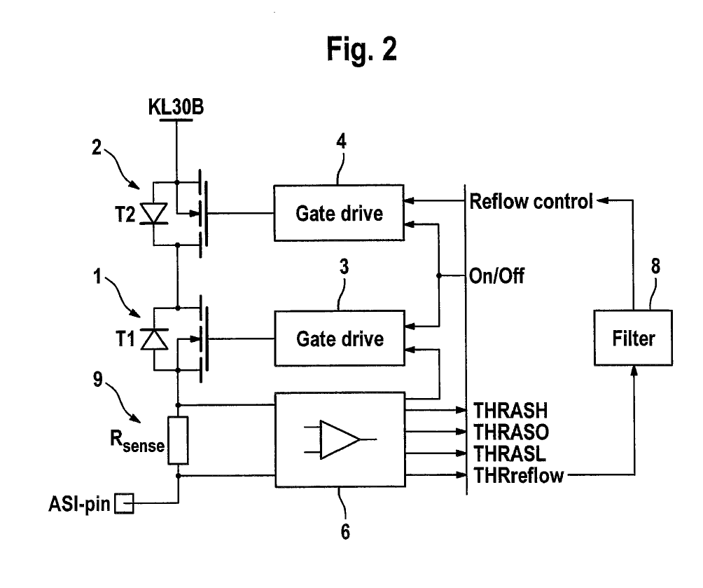

FIG. 2 shows a circuit arrangement which comprises the wheel rotational speed sensor channel of a motor vehicle control system. The energy supply of the wheel rotational speed sensor system ASI (Active Sensor Interface) is realized by way of the branch which includes a series connection of two self-blocking n-channel mosfets according to aspects of the invention. A supply current flows from terminal 30B into the ASI pin in the normal operating condition. Due to the voltage drop in a preceding protective circuit, the potential of terminal 30B is below the potential of the main energy supply. Now, the case may occur, e.g. due to the interaction of insulation deficiencies and the conducting vehicle body, that the supply voltage is applied in the area of the sensor interface. As a result, the potential of the ASI pin is above the potential of terminal 30B. In this case, reverse current flow into terminal 30B would take place, which might damage sensitive electronics in the signal path, as the case may be. An imminent or beginning reverse current flow is, however, detected by current monitoring 6 at resistor Rₛₑₙₛₒᵣ9. Different current thresholds THRs (Thresholds) can be detected with the aid of current monitoring 6. In particular, a threshold 1 with a lower value is defined, which allows detecting the start of an imminent reverse current flow THRreflow. This threshold 1 is evaluated by way of an interference filter 8 filtering admissible current fluctuations, especially short negative current impulses. The output of the filter is connected to the gate drive 4 of mosfet 2. When the latter is blocked in the event of an appearing reverse current flow, reverse current flow into terminal 30B can be effectively prevented. As a result of a fault current that is detected by current monitoring 6, e.g. an excessive current value in the direction of KL 30B to the ASI pin, the gate drive 3 of mosfet 1 can be driven directly and the current flow disabled. An on/off functionality allows the motor vehicle control system to block also both mosfets 1, 2 and, thus, prevent current flow in both directions.

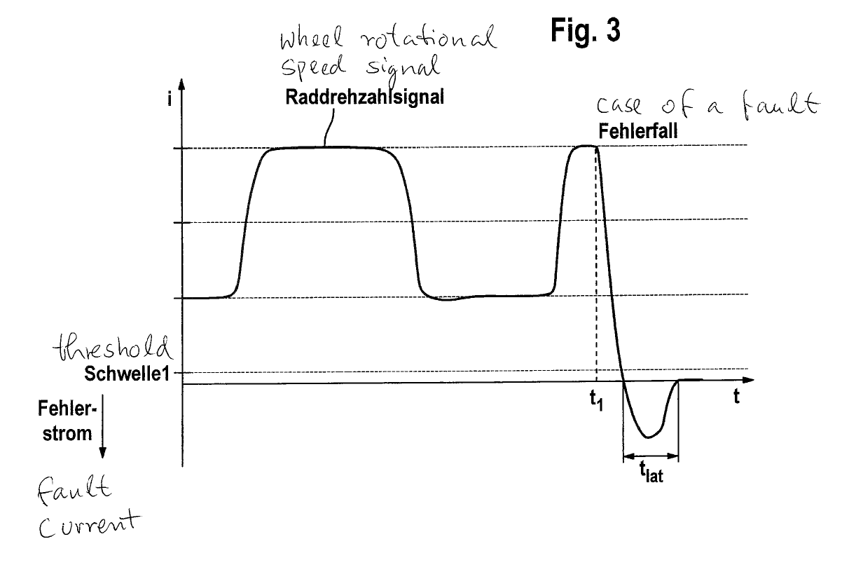

FIG. 3 illustrates the temporal current variation of the wheel rotational speed sensor channel. A case of a fault occurs after a certain time t₁. As a result, the current drops rapidly until below threshold 1. Current monitoring will recognize at this time that a fault exists and, possibly, reverse current flow is imminent. Therefore, the electronic control logic 5 will react by blocking mosfet 2, whereby the current flow is interrupted after a certain delay time tₗₐₜ. The duration of the delay time and, thus, also the maximum fault current value reached as well as the energy transmitted by it decisively depend on the level of the critical current threshold (threshold 1) and the filtering operation. It should be taken into account in this respect that an excessive approach which becomes effective even with very insignificant interferences will probably influence the sensor signal in an unwanted way. The function of the filter or of an algorithm stored in the electronic control logic 5 involves avoiding critical fault current values, while taking least possible influence on the sensor operation at the tame time.

While preferred embodiments of the invention have been described herein, it will be understood that such embodiments are provided by way of example only. Numerous variations, changes and substitutions will occur to those skilled in the art without departing from the spirit of the invention. It is intended that the appended claims cover all such variations as fall within the spirit and scope of the invention.

1-10. (canceled)

11. Circuit arrangement with a reverse current flow blocker for switching current flow in power applications,
wherein the circuit arrangement includes two serially connected mosfets on a branch to be switched, with the mosfets being connected such that inverse diodes of the mosfets are arranged opposite each other in terms of a PN junction of the mosfets.

12. Circuit arrangement as claimed in claim 11,
wherein each mosfet includes a gate drive for actuation, and the branch of each mosfet includes a device for current measurement.

13. Circuit arrangement as claimed in claim 11,
wherein a voltage that drops across the branch is applied to a comparator, and in that a defined offset voltage is predetermined for the comparator.

14. Circuit arrangement as claimed in claim 13,
wherein each mosfet includes a gate drive for actuation and wherein an output of the comparator is coupled to at least one of the gate drives.

15. Circuit arrangement as claimed in claim 12,
wherein the device for current measurement is a resistor across which a voltage drop is measured.

16. Circuit arrangement as claimed In claim 12,
wherein electronic control logic drives at least one mosfet gate drive, and the electronic control logic is linked to the current measurement device.

17. Circuit arrangement as claimed in claim 16,
wherein a current measured in the branch is supplied to the electronic control logic and is evaluated by the electronic control logic with respect to defined threshold values or by means of an algorithm, and the electronic control logic drives at least one mosfet gate drive corresponding to an evaluation of the current.

18. Circuit arrangement as claimed in claim 17,
wherein the current measured In the branch passes through an electronic filter prior to the evaluation by the electronic control logic.

19. Circuit arrangement as claimed in claim 11,
wherein at least one consumer is switched by way of the branch.

20. Circuit arrangement as claimed in claim 11 being integrated into a motor vehicle control system, a signal channel of a motor vehicle sensor system, or both a motor vehicle control system and a signal channel of a motor vehicle sensor system.

21. Use of the circuit arrangement as claimed in claim 11 in motor vehicles for regulation or control of electric signals and quantities on channels of sensors, sensor systems, or both sensors and sensor systems.
